(19) United States
(12) Patent Application Publication
(10) Pub. No.: US 2024/0079403 A1
(43) Pub. Date: Mar. 7, 2024

(54) METHOD FOR MANUFACTURING SUBSTRATE WITH CHIPS, AND SUBSTRATE PROCESSING DEVICE

(71) Applicant: Tokyo Electron Limited, Tokyo (JP)

(72) Inventors: Yoshihisa MATSUBARA, Tokyo (JP); Yoshihiro TSUTSUMI, Tokyo (JP); Yohei YAMASHITA, Kumamoto (JP)

(21) Appl. No.: 18/261,898

(22) PCT Filed: Jan. 18, 2022
(86) PCT No.: PCT/JP2022/001520

§ 371 Date: Jul. 18, 2023

(30) Foreign Application Priority Data
Jan. 29, 2021 (JP) 2021-013785

(51) Int. Cl. H01L 25/00; H01L 21/304; H01L 21/67; H01L 21/683; H01L 25/065

(52) U.S. Cl. CPC H01L 25/50; H01L 21/304; H01L 21/67132; H01L 21/6835; H01L 25/0652; H01L 2221/68309; H01L 2221/68327; H01L 2221/68368; H01L 2221/68381

(57) ABSTRACT

A method of manufacturing a substrate with chips includes the following (A) and (B):
(A) preparing a stacked substrate, the stacked substrate including: a plurality of chips; a first substrate to which the plurality of chips are temporarily bonded; and a second substrate bonded to the first substrate via the plurality of chips; and
(B) separating the plurality of chips bonded to the first substrate and the second substrate, from the first substrate, in order to bond the plurality of chips to one surface of a third substrate including a device layer.

In this method, the first substrate, from which the plurality of chips are separated, includes alignment marks that are used to ensure alignment when the first substrate and the plurality of chips are bonded together, or that are used to measure misalignment after the first substrate and the plurality of chips are bonded together.

### TECHNICAL FIELD

The present disclosure relates to a method of manufacturing a substrate with chips, and a substrate processing device.

### BACKGROUND ART

FIG. 20 of patent document 1 shows a chip-on-wafer manufacturing process. In this manufacturing process, individualized first memory chips are bonded, one by one, to a base wafer on which a plurality of second memory chips are formed.

### CITATION LIST

### Patent Document

[Patent Document 1] Japanese Unexamined Patent Application Publication No. 2015-46569

### SUMMARY OF THE INVENTION

### Problem to be Solved by the Invention

One aspect of the present disclosure provides a technique for reusing alignment marks that are used to ensure alignment when chips and a substrate are bonded together, or that are used to measure the misalignment after chips and a substrate are bonded together.

### Means to Solve the Problem

A method of manufacturing a substrate with chips according to one aspect of the present disclosure includes the following (A) and (B):
(A) preparing a stacked substrate, the stacked substrate including: a plurality of chips; a first substrate to which the plurality of chips are temporarily bonded; and a second substrate bonded to the first substrate via the plurality of chips; and
(B) separating the plurality of chips bonded to the first substrate and the second substrate, from the first substrate, in order to bond the plurality of chips to one surface of a third substrate including a device layer.

In this method, the first substrate, from which the plurality of chips are separated, includes alignment marks that are used to ensure alignment when the first substrate and the plurality of chips are bonded together, or that are used to measure misalignment after the first substrate and the plurality of chips are bonded together.

### Effects of the Invention

According to one aspect of the present disclosure, alignment marks can be reused.

### BRIEF DESCRIPTION OF THE DRAWINGS

FIG. 1 is a flowchart that shows a method of manufacturing a substrate with chips according to one embodiment;

FIG. 2 is a flowchart that shows S1 in FIG. 1 in detail;

FIG. 3 is a flowchart that shows S6 in FIG. 1 in detail;

FIG. 4 is a cross-sectional view that shows a state during S1 in FIG. 1;

FIG. 5 is a cross-sectional view that shows a state upon completion of S1 in FIG. 1;

FIG. 6 is a cross-sectional view that shows a state upon completion of S2 in FIG. 1;

FIG. 7 is a cross-sectional view that shows a state upon completion of S3 in FIG. 1;

FIG. 8 is a cross-sectional view that shows a state during S4 in FIG. 1;

FIG. 9 is a cross-sectional view that shows a state upon completion of S4 in FIG. 1;

FIG. 10 is a cross-sectional view that shows a state upon completion of S5 in FIG. 1;

FIG. 11 is a cross-sectional view that shows a state upon completion of S61 in FIG. 3, which is included in S6 in FIG. 1;

FIG. 12 is a cross-sectional view that shows a state upon completion of S62 in FIG. 3, which is included in S6 in FIG. 1;

FIG. 13 is a cross-sectional view that shows a state upon completion of S63 in FIG. 3, which is included in S6 in FIG. 1;

FIG. 14 is a cross-sectional view that shows a state upon completion of S7 in FIG. 1;

FIG. 15A is a cross-sectional view that shows an example of a first step of a Ge film forming method;

FIG. 15B is a cross-sectional view that shows an example of a second step of the Ge film forming method;

FIG. 15C is a cross-sectional view that shows an example of a third step of the Ge film forming method;

FIG. 15D is a cross-sectional view that shows an example of a fourth step of the Ge film forming method;

FIG. 15E is a cross-sectional view that shows an example of a fifth step of the Ge film forming method;

FIG. 15F is a cross-sectional view that shows an example of a sixth step of the Ge film forming method;

FIG. 16 is a diagram that shows an example of transmittance of an SiGe film;

FIG. 17A is a cross-sectional view that shows an example of a first step in a method of forming a metal silicide film;

FIG. 17B is a cross-sectional view that shows an example of a second step in the method of forming a metal silicide film;

FIG. 17C is a cross-sectional view that shows an example of a third step in the method of forming a metal silicide film;

FIG. 17D is a cross-sectional view that shows an example of a fourth step in the method of forming a metal silicide film;

FIG. 17E is a cross-sectional view that shows an example of a fifth step in the method of forming a metal silicide film;

FIG. 17F is a cross-sectional view that shows an example of a sixth step in the method of forming a metal silicide film;

FIG. 17G is a cross-sectional view that shows an example of a seventh step in the method of forming a metal silicide film;

FIG. 18 is a diagram that shows an example of absorptance of a metal silicide film;

FIG. 19A is a cross-sectional view that shows an example of a first step in a method of forming an AlN film;

FIG. 19B is a cross-sectional view that shows an example of a second step in the method of forming an AlN film;

FIG. 19C is a cross-sectional view that shows an example of a third step in the method of forming an AlN film;

FIG. 19D is a cross-sectional view that shows an example of a fourth step in the method of forming an AlN film;

FIG. 19E is a cross-sectional view that shows an example of a fifth step in the method of forming an AlN film;

FIG. 19F is a cross-sectional view that shows an example of a sixth step in the method of forming an AlN film;

FIG. 19G is a cross-sectional view that shows an example of a seventh step in the method of forming an AlN film;

FIG. 20 is a diagram that shows an example of the transmittance of an AlN film; and

FIG. 21 is a plan view that shows a substrate processing device according to one embodiment.

### MODE FOR CARRYING OUT THE INVENTION

Hereinafter, an embodiment of the present disclosure will be described with reference to the accompanying drawings. Note that, in each of the accompanying drawings, the same reference numerals/signs are assigned to the same or corresponding parts, and redundant description may be omitted.

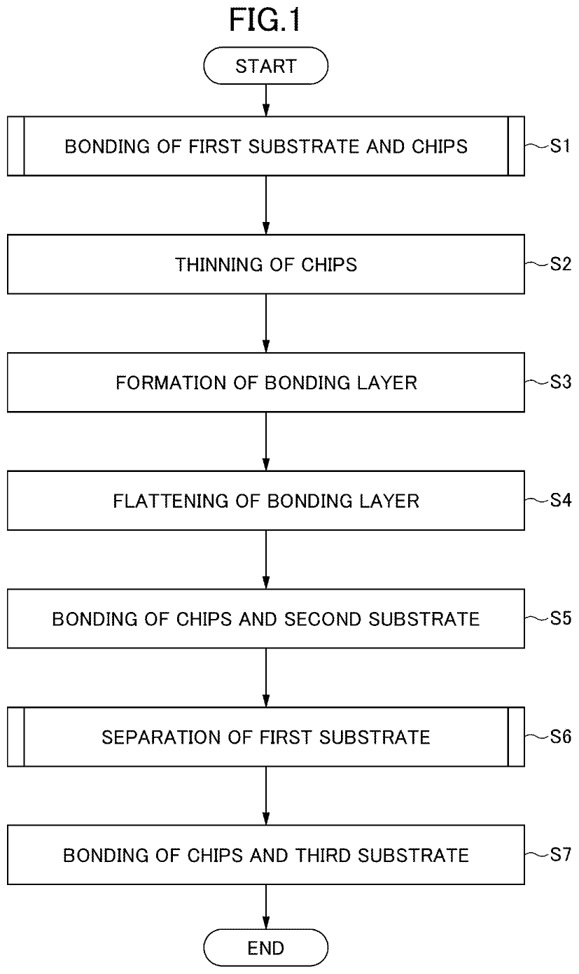

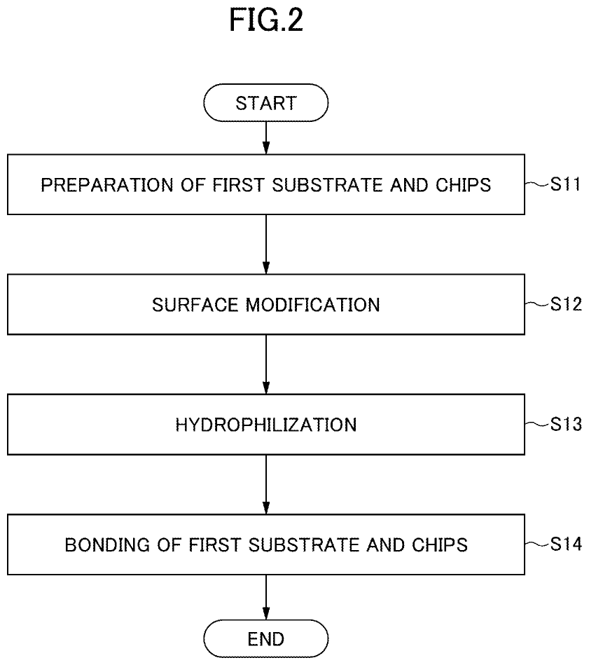

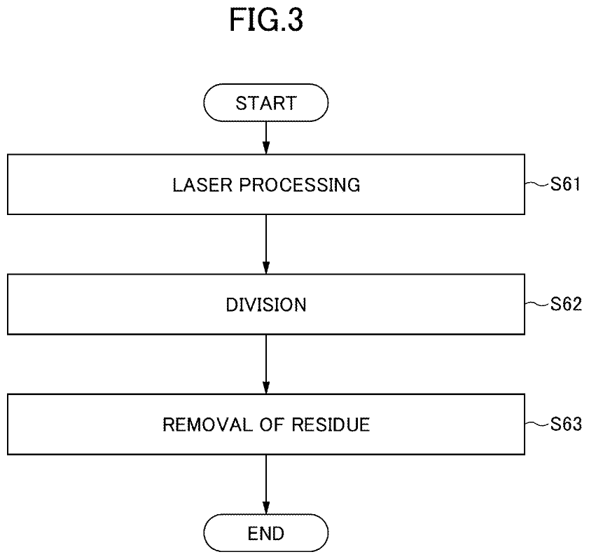

A method of manufacturing a substrate with chips includes, for example, S1 to S7 shown in FIG. 1. S1 in FIG. 1 includes, for example, S11 to S14 shown in FIG. 2. Also, S6 shown in FIG. 1 includes, for example, S61 to S63 shown in FIG. 3.

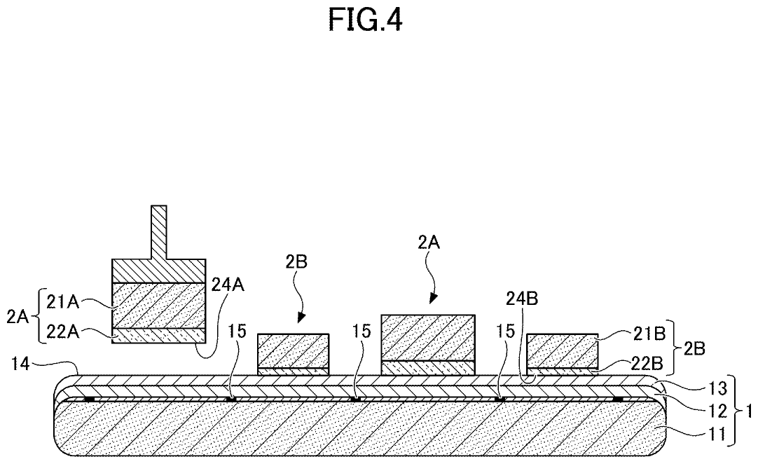

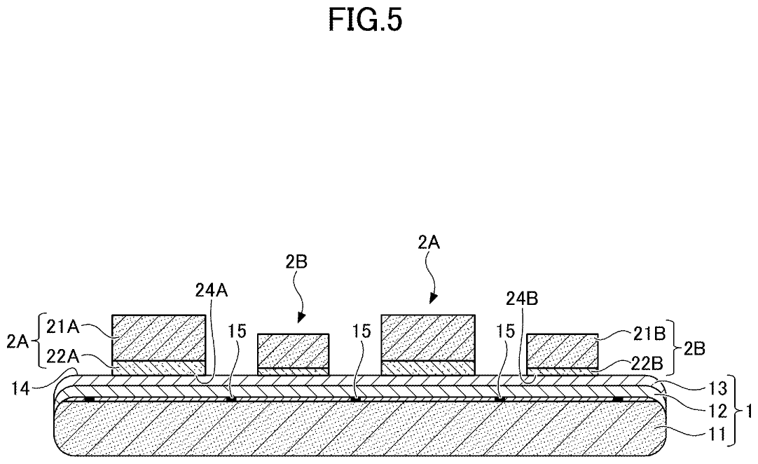

First, in S1 of FIG. 1, as shown in FIG. 4 and FIG. 5, a first substrate 1 and chips 2A and 2B are bonded together. In S11 of FIG. 2, which is included in S1 of FIG. 1, the first substrate 1 and the chips 2A and 2B are prepared.

The first substrate 1 has, for example, a silicon wafer 11, an absorption layer 12, and a bonding layer 13. Note that the absorption layer 12 may also serve as the bonding layer 13, as will be described later, and the first substrate 1 may only have the silicon wafer 11 and the absorption layer 12. A compound semiconductor wafer may be used instead of the silicon wafer 11. The compound semiconductor wafer is not particularly limited, and may be, for example, a GaAs wafer, an SiC wafer, a GaN wafer, an InP wafer, or an AlN wafer.

The absorption layer 12 is placed between the silicon wafer 11 and the chips 2A and 2B. Although this will be described later in detail, as shown in FIG. 11, a laser beam LB2 passes through the silicon wafer 11 and is absorbed by the absorption layer 12. Since the laser beam LB2 is absorbed by the absorption layer 12 and does not hit the chips 2A and 2B, damage to the chips 2A and 2B can be mitigated. The absorption layer 12 is, for example, a silicon oxide layer, and is formed by thermal oxidation, chemical vapor deposition (CVD), and so forth.

Note that the absorption layer 12 has only to absorb the laser beam LB2 to an extent that damage to the chips 2A and 2B can be mitigated, and may be a silicon nitride layer, a silicon carbonitride layer, or the like. The silicon nitride layer may be formed by thermal nitridation, CVD, or the like. The silicon carbonitride layer may be formed by CVD or the like.

The bonding layer 13 is placed between the absorption layer 12 and the chips 2A and 2B, and contacts the chips 2A and 2B, as shown in FIG. 4. The bonding layer 13 is, for example, an insulating layer such as a silicon oxide layer. The bonding layer 13 may be made of a material that is different from that of the absorption layer 12, or may be made of the same material. In the latter case, the absorption layer 12 may also serve as the bonding layer 13.

The first substrate 1 includes alignment marks 15. The alignment marks 15 are used to ensure alignment when the first substrate 1 and the chips 2A and 2B are bonded together, or to measure the misalignment after the first substrate 1 and the chips 2A and 2B are bonded together. The alignment marks 15 may be used for both ensuring alignment and measuring misalignment. The result of measuring the misalignment after the first substrate 1 and the chips 2A and 2B are bonded together may be used, for example, to ensure alignment when bonding the first substrate 1 and the chips together from the next time onward. Also, the result of measuring the misalignment after the first substrate 1 and the chips are bonded together may be used for quality control such as when finding defective products.

The alignment marks 15 are formed between the silicon wafer 11 and the absorption layer 12, as shown in FIG. 12, and formed on the opposite side from the chips 2A and 2B, with respect to a dividing surface D. By dividing the first substrate 1 at the dividing surface D, the silicon wafer 11 can be separated from the chips 2A and 2B. The alignment marks 15 are in the silicon wafer 11, separated from the chips 2A and 2B. Therefore, when the silicon wafer 11 is reused, the alignment marks 15 can be reused without having to re-form the alignment marks 15.

The alignment marks 15 absorb the infrared rays used to photograph the alignment marks 15. An infrared camera photographs the alignment marks 15 by receiving the infrared rays that pass through the silicon wafer 11. Unlike the wavelength of the laser beam LB2, the wavelength of the infrared rays used for photographing the alignment marks 15 is, for example, 1,000 nm to 2,000 nm. The absorptance of infrared rays used to photograph the alignment marks 15 is, for example, 45% or more and 100% or less, preferably 50% or more and 100% or less, and more preferably 60% or more and 100% or less.

The alignment marks 15 allow the laser beam LB2 to pass therethrough, as shown in FIG. 11. The laser beam LB2 passes through the silicon wafer 11 and the alignment marks 15, thereby forming modified layer portions M in the absorption layer 12. The modified layer portions M are formed as the absorption layer 12 absorbs the laser beam LB2. A plurality of modified layer portions M are formed in the dividing surface D. The first substrate 1 is divided by using the modified layer portions M as starting points. The wavelength of the laser beam LB2 is, for example, 8,800 nm to 11,000 nm. The transmittance of the laser beam LB2 through the alignment marks 15 is, for example, 45% or more and 100% or less, preferably 50% or more and 100% or less, and more preferably 60% or more and 100% or less.

As described above, the alignment marks 15 are made of a material that absorbs the infrared rays used to photograph the alignment marks 15, and that allows the laser beam LB2 to pass therethrough. To be more specific, for example, the alignment marks 15 include a Ge film, an SiGe film, a metal silicide film, or an AlN film. Unlike an SiO₂ film and a metal film, a Ge film absorbs the infrared rays for photographing the alignment marks 15 and allows the laser beam LB2 to pass therethrough. Incidentally, an SiO₂ film allows the infrared rays for photographing the alignment marks 15 to pass therethrough, and absorbs the laser beam LB2. Furthermore, although a metal film can absorb the infrared rays for photographing the alignment marks 15, it ends up absorbing the laser beam LB2 as well. The method of forming the alignment marks 15 will be described later.

The chips 2A have a silicon wafer 21A and a device layer 22A. The device layer 22A is formed on the surface of the silicon wafer 21A. The device layer 22A includes semiconductor elements, circuits, terminals, and so forth. After the device layer 22A is formed, the silicon wafer 21A is individualized to a plurality of chips 2A.

The chips 2B, like the chips 2A, have a silicon wafer 21B and a device layer 22B. The device layer 22B has different functions from the device layer 22A, and the chips 2A and the chips 2B have different thicknesses. After the device layer 22B is formed, the silicon wafer 21B is individualized to a plurality of chips 2B.

In S12 of FIG. 2, which is included in S1 of FIG. 1, the bonding surface 14 of the first substrate 1 is surface-modified with plasma or the like. To be more specific, the SiO₂ bonding of the bonding surface 14 is cut, Si dangling bonds are formed, and the bonding surface 14 is made ready for hydrophilization.

For example, in a reduced-pressure atmosphere, oxygen gas, which is the processing gas, is excited into plasma state and ionized. Oxygen ions are emitted onto the bonding surface 14, thereby modifying the bonding surface 14. The processing gas is by no means limited to oxygen gas, and may be, for example, nitrogen gas or the like.

In S12 above, not only the bonding surface 14 of the first substrate 1, but also the bonding surfaces 24A and 24B of the chips 2A and 2B may be surface-modified as well. At least one of the bonding surface 14 of the first substrate 1, and the bonding surfaces 24A and 24B of the chips 2A and 2B, may be surface-modified.

In S13 of FIG. 2, which is included in S1 of FIG. 1, the bonding surface 14 of the first substrate 1 is made hydrophilic. For example, the first substrate 1 is held by a spin chuck, and pure water such as deionized water (DIW) is supplied to the bonding surface 14 of the first substrate 1 that rotates with the spin chuck. An OH group is attached to the Si dangling bonds of the bonding surface 14, and the bonding surface 14 is made hydrophilic.

In S13 above, not only the bonding surface 14 of the first substrate 1, but also the bonding surfaces 24A and 24B of the chips 2A and 2B may be made hydrophilic as well. At least one of the bonding surface 14 of the first substrate 1, and the bonding surfaces 24A and 24B of the chips 2A and 2B, may be made hydrophilic.

In S14 of FIG. 2, which is included in S1 of FIG. 1, the chips 2A and 2B are temporarily bonded, one by one, to the bonding surface 14 of the first substrate 1. The chips 2A and 2B are bonded to the first substrate 1 with the device layers 22A and 22B facing the first substrate 1.

The chips 2A and 2B and the first substrate 1 are bonded together by, for example, van der Waals forces (intermolecular forces), hydrogen bonding between OH groups, and so forth. Subsequently, heat treatment may be applied in order to increase the bonding strength. The heat treatment causes a dehydration reaction. Since solids are directly bonded to each other without using a liquid adhesive, it is possible to prevent misalignment due to change of the shape of the adhesive, and prevent inclination from being produced due to uneven thickness of the adhesive.

Now, according to patent document 1 mentioned earlier, unlike the technique of the present disclosure, chips 2A and 2B are permanently bonded to a third substrate 6, which will be described later, without going through the step of temporarily bonding the chips 2A and 2B to the first substrate 1. Therefore, upon bonding, it is necessary to both prevent air bubbles and foreign matter from getting caught, and perform position control accurately, at the same time.

When bonding the chips 2A and 2B to the third substrate 6 one by one as in patent document 1, the chips 2A and 2B may be deformed one by one so as to prevent air bubbles from getting caught upon bonding. The bonding surfaces 24A and 24B of the chips 2A and 2B are deformed into downwardly protruding curved surfaces, bonded with the third substrate 6 gradually from the center to the periphery, and finally resume flat surfaces.

Changing the bonding surfaces 24A and 24B of the chips 2A and 2B to downwardly protruding curved surfaces includes fixing the respective peripheries of the chips 2A and 2B and pressing the respective centers of the chips 2A and 2B downward. However, since the chips 2A and 2B are both small in size and the fixing points and the pressing points are placed at short intervals, it is difficult to deform the chips 2A and 2B one by one.

According to this embodiment, the chips 2A and 2B are temporarily bonded to the first substrate 1, and later separated from the first substrate 1. That is, there is no problem even if air bubbles are caught when the chips 2A and 2B and the first substrate 1 are bonded together. Therefore, in S14 above, the bonding surfaces 24A and 24B of the chips 2A and 2B can be kept flat and bonded to the bonding surface 14 of the first substrate 1. Since the chips 2A and 2B are not deformed, the accuracy of position control for the chips 2A and 2B can be improved, and the chips 2A and 2B can be accurately placed in intended positions.

Also, according to this embodiment, the chips 2A and 2B are temporarily bonded to the first substrate 1 and later separated from the first substrate 1. That is, there is no problem even if particles are caught when the chips 2A and 2B and the first substrate 1 are bonded together. Therefore, the bonding surface 14 of the first substrate 1 and the bonding surfaces 24A and 24B of the chips 2A and 2B may be dirty to an extent that bonding is not hindered. That is, the cleanliness to be required is mitigated.

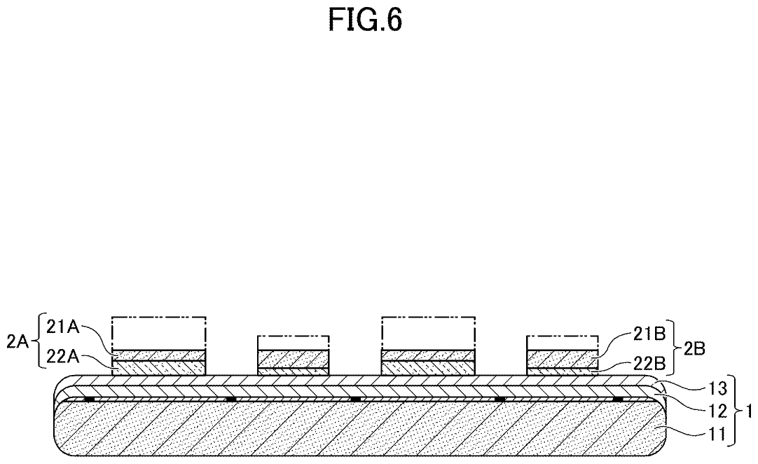

Next, in S2 of FIG. 1, as shown in FIG. 6, the chips 2A and 2B are made thin so as to have a uniform thickness. In FIG. 6, the two-dot chain line indicates the state shortly before S2, and the solid line indicates the state upon completion of S2. In the chips 2A and 2B, the silicon wafers 21A and 21B are made thin, and the device layers 22A and 22B are not made thin. The thinning may include grinding or laser processing.

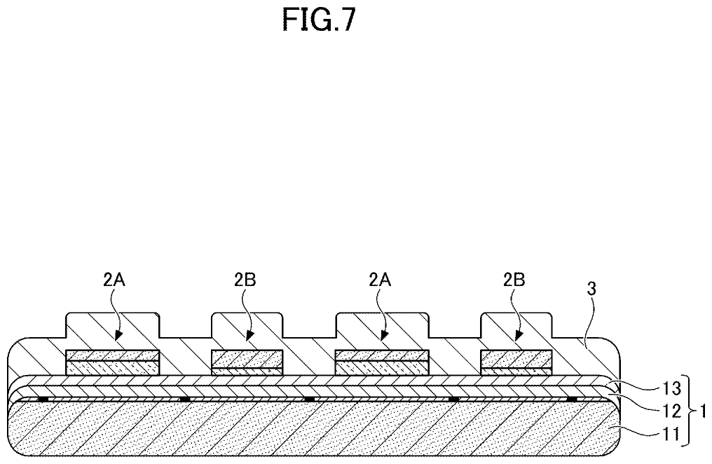

Next, in S3 of FIG. 1, as shown in FIG. 7, a bonding layer 3 is formed over the surfaces of the chips 2A and 2B. The bonding layer 3 is an insulating layer such as a silicon oxide layer, like the bonding layer 13 of the first substrate 1, and is formed by CVD or the like. Since the chips 2A and 2B are spaced apart from each other and the underlying surface of the bonding layer 3 is uneven, the surface of the bonding layer 3 is also uneven.

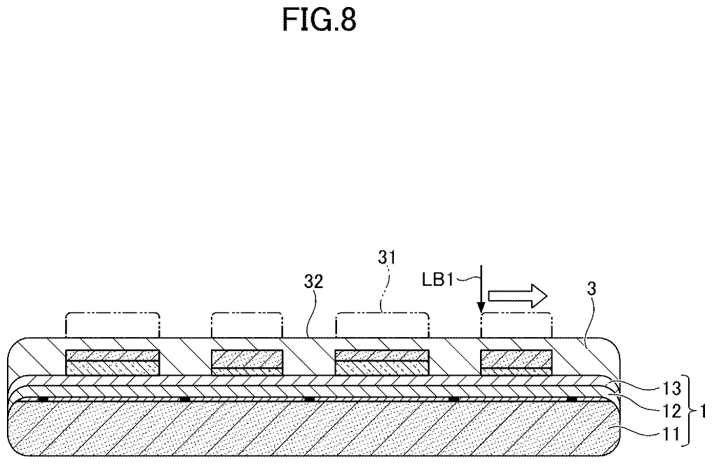

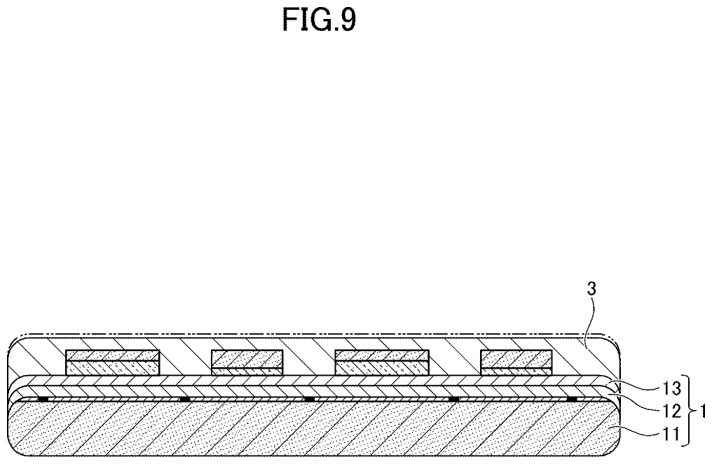

Next, in S4 of FIG. 1, as shown in FIG. 8 and FIG. 9, the surface of the bonding layer 3 is flattened. Since the bonding layer 3 is a silicon oxide layer or the like and has high hardness, flattening by polishing such as chemical mechanical polishing (CMP) takes time.

Therefore, first, as shown in FIG. 8, protruding parts 31 of the bonding layer 3 are irradiated with the laser beam LB1. The protruding parts 31 absorb the laser beam LB1, and change their state from the solid phase to the gas phase and are dispersed or are dispersed in the solid phase, on an as-is basis. Note that the laser beam LB1 may also irradiate the recessed parts 32 of the bonding layer 3 as well. If the intensity of irradiation in the recessed parts 32 is lower than in the protruding parts 31, the surface of the bonding layer 3 can be flattened.

The irradiation point of the laser beam LB1 is moved by a galvanometer scanner or an XYθ stage. The galvanometer scanner moves the laser beam LB1. The XYθ stage moves the first substrate 1 horizontally (in the X-axis direction and the Y-axis direction) and rotates it about the vertical axis. An XYZθ stage may be used instead of the XYθ stage.

Following this, as shown in FIG. 9, the surface of the bonding layer 3 is flattened further by CMP or the like. Since the protruding parts 31 are already selectively removed prior to CMP, the waviness that remains on the surface of the bonding layer 3 after CMP can be reduced.

Next, in S5 of FIG. 1, the chips 2A and 2B and a second substrate 5 are bonded together as shown in FIG. 10. The second substrate 5 contacts the flattened surface of the bonding layer 3, and is bonded with the chips 2A and 2B via the bonding layer 3.

The second substrate 5 has, for example, a silicon wafer 51 and a bonding layer 53. The bonding layer 53 is an insulating layer such as a silicon oxide layer, like the bonding layer 13 of the first substrate 1, and is formed by CVD or the like.

At least one of the bonding surface 54 of the second substrate 5 and the bonding surface 34 of the bonding layer 3 may be subjected to surface modification and hydrophilization prior to bonding. The second substrate 5 and the bonding layer 3 are bonded by, for example, van der Waals forces (intermolecular forces), hydrogen bonding between OH groups, and so forth. Since solids are directly bonded together without using a liquid adhesive, it is possible to prevent misalignment due to, for example, change of the shape of the adhesive. Furthermore, it is possible to prevent inclination from being produced due to uneven thickness of the adhesive.

The second substrate 5 is bonded to the first substrate 1 via the bonding layer 3 with its bonding surface 54 facing downward. In other words, substrates are bonded together. In doing so, the bonding surface 54 of the second substrate 5 is deformed to a downwardly protruding curved surface, so as to prevent air bubbles from getting caught, bonded with the first substrate 1 gradually from the center to the periphery, and finally resumes a flat surface.

The second substrate 5 can be deformed by fixing the periphery of the second substrate 5 and pressing the center of the second substrate 5 downward. When deforming the second substrate 5, the distance between the fixing point and the pressing point is wide compared to the case in which the chips 2A and 2B are deformed one by one, so that it is easy to deform the second substrate 5. The reason deformation is easy is that substrates are bonded together.

Note that the positions of the second substrate 5 and the first substrate 1 may be reversed. That is, the second substrate 5 may be placed below the first substrate 1, or the bonding surface 54 of the second substrate 5 may face upward. In this case, the bonding surface 54 of the second substrate 5 is deformed to an upwardly protruding curved surface, so as to prevent air bubbles from getting caught, bonded with the first substrate 1 gradually from the center to the periphery, and finally resumes a flat surface.

Note that the second substrate 5 and the first substrate 1 are bonded together by bending the second substrate 5 first, in order to bond the second substrate 5 and the first substrate 1 together gradually from the center toward the periphery, but it is equally possible to bend and deform the first substrate 1 first. In this case, too, substrates are bonded together. However, from the perspective of protecting the chips 2A and 2B, it is preferable to keep the first substrate 1 flat and keep the chips 2A and 2B flat.

Next, in S6 of FIG. 1, the chips 2A and 2B are separated from the first substrate 1 as shown in FIG. 11, FIG. 12, and FIG. 13. In S61 of FIG. 3, which is included in S6 of FIG. 1, as shown in FIG. 11, a plurality of modified layer portions M are formed by the laser beam LB2, in the dividing surface D where the first substrate 1 is going to be divided in the thickness direction. The modified layer portions M are formed in a dot-like shape, for example, at the focal point or above the focal point.

The laser beam LB2 passes through the silicon wafer 11 of the first substrate 1, and forms the modified layer portions M in the absorption layer 12 of the first substrate 1. The absorption layer 12 is placed between the silicon wafer 11 and the chips 2A and 2B, and absorbs the laser beam LB2. Since the laser beam LB2 does not appreciably hit the chips 2A and 2B, damage to the chips 2A and 2B can be mitigated.

The laser beam LB2 has a wavelength of, for example, 8,800 nm to 11,000 nm, so as to pass through the silicon wafer 11 and the alignment marks 15, and be absorbed by the absorption layer 12. The light source of the laser beam LB2 is, for example, a CO₂ laser. The wavelength of a CO₂ laser is approximately 9,300 nm. The laser beam LB2 is pulsed.

The positions where the modified layer portions M are formed are moved by a galvanometer scanner or an XYθ stage. The galvanometer scanner moves the laser beam LB2. The XYθ stage moves the first substrate 1 horizontally (in the X-axis direction and the Y-axis direction) and rotates it about the vertical axis. An XYZθ stage may be used instead of the XYθ stage.

A plurality of modified layer portions M are formed at intervals in the circumferential and radial directions of the first substrate 1. When the modified layer portions M are formed, a crack CR that connects between the modified layer portions M is also formed.

In S62 of FIG. 3, which is included in S6 of FIG. 1, the first substrate 1 is divided by using the modified layer portions M as starting points, as shown in FIG. 12. First, the upper chuck 131 holds the first substrate 1, and the lower chuck 132 holds the second substrate 5. However, the positions of the first substrate 1 and the second substrate 5 may be reversed vertically, and the upper chuck 131 may hold the second substrate 5, while the lower chuck 132 holds the first substrate 1. Next, when the upper chuck 131 rises with respect to the lower chuck 132, the crack CR expands planarly from the modified layer portions M as starting points, and the first substrate 1 is divided at the dividing surface D.

In above S62, the upper chuck 131 may rotate about the vertical axis as the upper chuck 131 rises. The first substrate 1 can be threaded off at the dividing surface D. Note that, instead of raising the upper chuck 131 or in addition to raising the upper chuck 131, the lower chuck 132 may be lowered. Also, the lower chuck 132 may be rotated about the vertical axis.

In S63 of FIG. 3, which is included in S6 of FIG. 1, as shown in FIG. 13, a residue 16 of the first substrate 1 attached to the chips 2A and 2B is removed by CMP or the like. The residue 16 includes part of the absorption layer 12, and the bonding layer 13. After the residue 16 is removed, the device layers 22A and 22B of the chips 2A and 2B are exposed again. The device layers 22A and 22B are semiconductor memories, for example.

Next, in S7 of FIG. 1, as shown in FIG. 14, the chips 2A and 2B are bonded to the second substrate 5, and, keeping this state, bonded to one surface 64 of the third substrate 6 including the device layer 62. The third substrate 6 includes a silicon wafer 61 and the device layer 62.

The device layer 62 is formed over the surface of the silicon wafer 61. The device layer 62 includes semiconductor elements, circuits, terminals, and so forth, and is electrically connected to the device layers 22A and 22B of the chips 2A and 2B. The device layer 62 may be, for example, a semiconductor memory's peripheral circuit (also referred to as a “peripheral”) or a semiconductor memory's input/output circuit (also referred to as an “IO”).

At least one of the bonding surface 64 of the third substrate 6 and the bonding surfaces 24A and 24B of the chips 2A and 2B may be subjected to surface modification and hydrophilization prior to bonding. The third substrate 6 and the chips 2A and 2B are bonded together by, for example, van der Waals forces (intermolecular forces), hydrogen bonding between OH groups, and so forth. Since solids are directly bonded together without using a liquid adhesive, it is possible to prevent misalignment due to, for example, change of the shape of the adhesive. Furthermore, it is possible to prevent inclination from being produced due to uneven thickness of the adhesive.

The third substrate 6 is bonded to the second substrate 5 via the chips 2A and 2B with its bonding surface 64 facing downward. In other words, substrates are bonded together. In doing so, the bonding surface 64 of the third substrate 6 is deformed to a downwardly protruding curved surface, so as to prevent air bubbles from getting caught, bonded with the second substrate 5 gradually from the center to the periphery, and finally resumes a flat surface.

The third substrate 6 can be deformed by fixing the periphery of the third substrate 6 and pressing the center of the third substrate 6 downward. When deforming the third substrate 6, the distance between the fixing point and the pressing point is wide compared to the case in which the chips 2A and 2B are deformed one by one, so that it is easy to deform the third substrate 6. The reason deformation is easy is that substrates are bonded together.

Note that the positions of the third substrate 6 and the second substrate 5 may be reversed. That is, the third substrate 6 may be placed below the second substrate 5, or the bonding surface 64 of the third substrate 6 may face upward. In this case, the bonding surface 64 of the third substrate 6 is deformed to an upwardly protruding curved surface, so as to prevent air bubbles from getting caught, bonded with the second substrate 5 gradually from the center to the periphery, and finally resumes a flat surface. In this case, too, substrates are bonded together.

Note that the third substrate 6 and the second substrate 5 are bonded together by bending the third substrate 6 first, in order to bond the third substrate 6 and the second substrate 5 together gradually from the center toward the periphery, but it is equally possible to bend and deform the second substrate 5 first. In this case, too, substrates are bonded together.

A substrate 7 with chips is obtained through above S7. The substrate 7 with chips includes a third substrate 6 and a plurality of chips 2A and 2B. The substrate 7 with chips further includes a second substrate 5. Note that the second substrate 5 may be separated from the chips 2A and 2B, and the substrate 7 with chips has only to include the third substrate 6 and the chips 2A and 2B.

As described above, according to this embodiment, to obtain the substrate 7 with chips, the chips 2A and 2B are first bonded to one surface of the first substrate on a temporary basis, instead of bonding the chips 2A and 2B to one surface of the third substrate 6 one by one. Since the inclusion of air bubbles at this stage does not pose a problem, the bonding surfaces 24A and 24B of the chips 2A and 2B can be kept flat and bonded to the bonding surface 14 of the first substrate 1. The chips 2A and 2B need not be deformed forcibly, so that the accuracy of position control for the chips 2A and 2B can be improved, and the chips 2A and 2B can be accurately placed in intended positions.

Subsequently, the chips 2A and 2B bonded to the first substrate 1 are bonded to the surface of the second substrate 5 facing the first substrate 1. Following this, the chips 2A and 2B, bonded to the first substrate 1 and the second substrate 5, are separated from the first substrate 1. Next, the chips 2A and 2B separated from the first substrate 1 are bonded to the second substrate 5, and, keeping this state, bonded to one surface 64 of the third substrate 6 including the device layer 62.

In doing so, the bonding surface 64 of the third substrate 6 is deformed to a downwardly protruding curved surface, so as to prevent air bubbles from getting caught, bonded with the second substrate 5 gradually from the center to the periphery, and finally resumes a flat surface. Deforming the third substrate 6 is easier than deforming the chips 2A and 2B one by one. The reason this deformation is easy is that substrates are bonded together. Therefore, unlike above-mentioned patent document 1, it is not necessary to perform the step of temporarily bonding the chips 2A and 2B to the first substrate 1, and, unlike the case in which the chips 2A and 2B are bonded to the third substrate 6 permanently, no air bubbles get caught, so that a substrate 7 with chips with high accuracy of positioning can be obtained.

Also, according to this embodiment, the alignment marks 15 are in the silicon wafer 11 that is separated from the chips 2A and 2B. Therefore, when the silicon wafer 11 is reused, the alignment marks 15 can be reused without having to re-form the alignment marks 15. The silicon wafer 11, separated from the chips 2A and 2B, is bonded to chips other than the chips 2A and 2B.

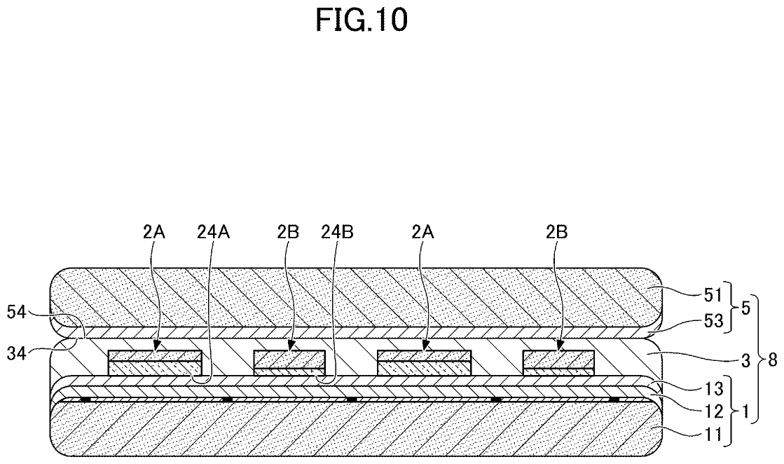

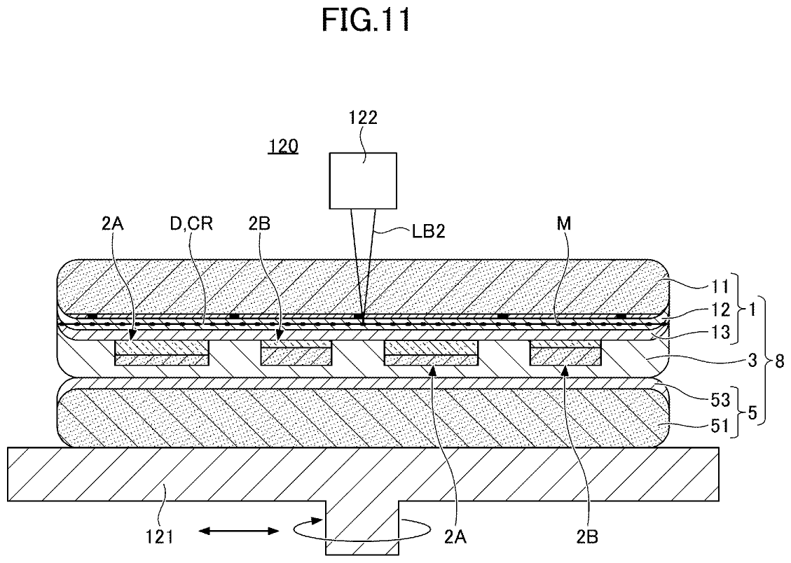

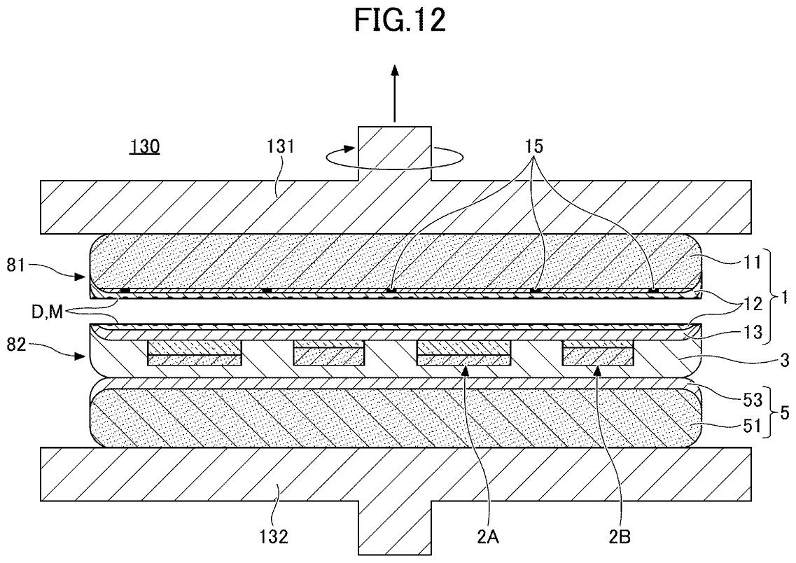

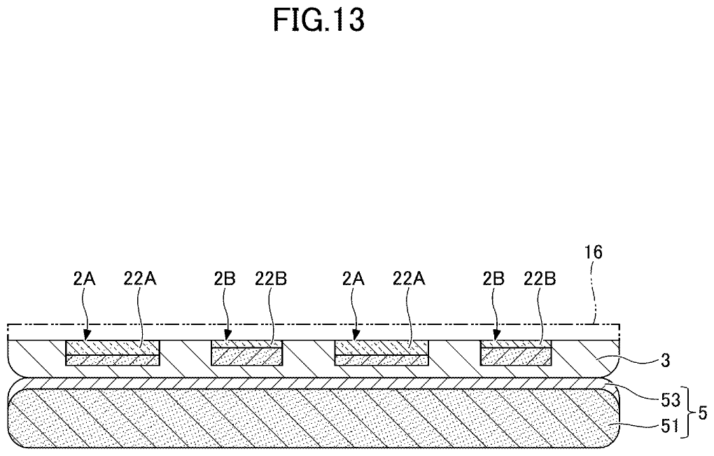

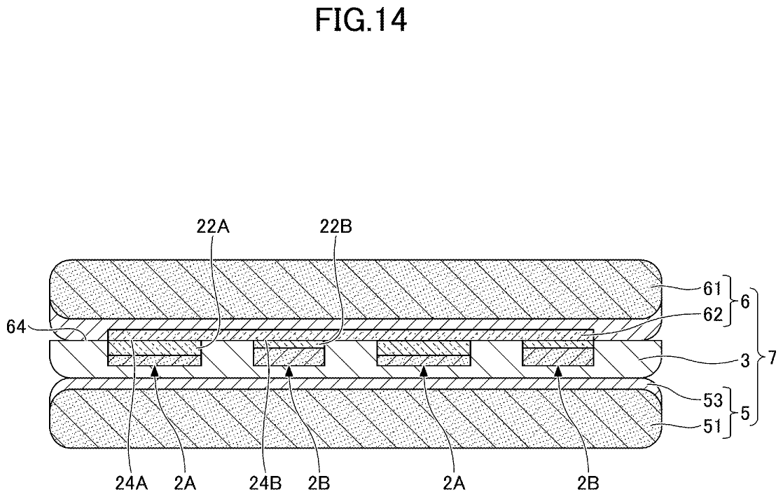

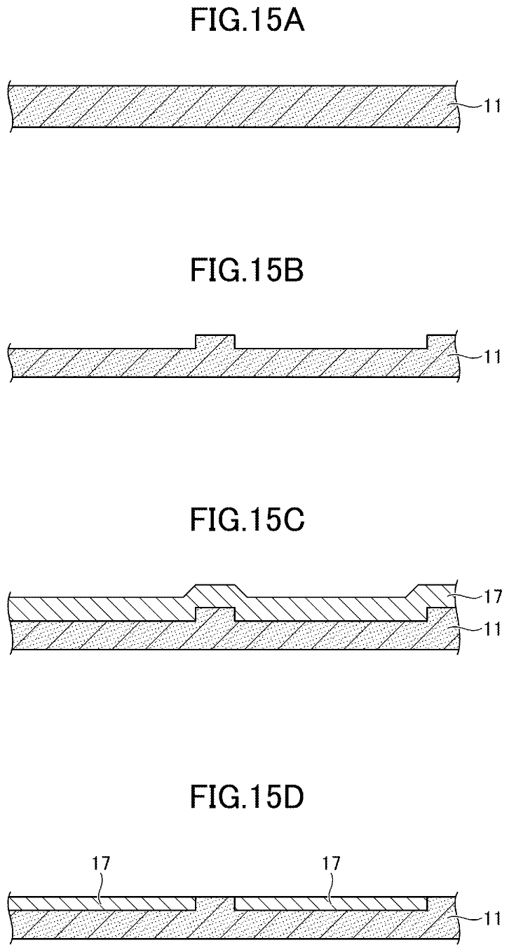

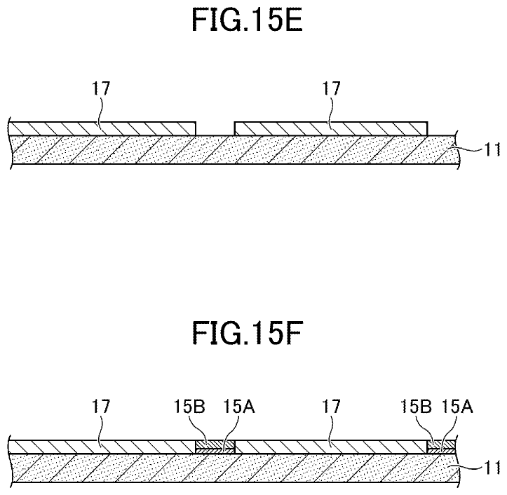

Next, a method of forming a Ge film, which serves as alignment marks, will be described with reference to FIGS. 15A to 15F. The forming method includes first to sixth steps. In the first step, a silicon wafer 11 is prepared as shown in FIG. 15A.

In the second step, the surface of the silicon wafer 11 is etched to form trenches, as shown in FIG. 15B. The depth of the trenches is not particularly limited, and may be, for example, 100 nm.

In the third step, an SiO₂ film 17 is formed over the surface of the silicon wafer 11, and the trenches are filled with the SiO₂ film 17, as shown in FIG. 15C. The SiO₂ film 17 is formed by, for example, CVD using tetraethoxysilane (TEOS). The film thickness of the SiO₂ film 17 is not particularly limited, and may be, for example, 100 nm.

In the fourth step, as shown in FIG. 15D, the SiO₂ film 17 is flattened by CMP or the like, to expose part of the surface of the silicon wafer 11. The rest of the surface of the silicon wafer 11 is covered with the SiO₂ film 17. The film thickness of the remaining SiO₂ film 17 is not particularly limited, and may be, for example, 100 nm.

In the fifth step, as shown in FIG. 15E, the exposed surface of the silicon wafer 11 is etched to form trenches between SiO₂ films 17. The depth of the trenches is not particularly limited, and may be, for example, 100 nm.

In the sixth step, as shown in FIG. 15F, an SiGe film 15A is epitaxially grown on the bottom surface of the trenches of the silicon wafer 11, and a Ge film 15B is epitaxially grown over the SiGe film 15A. Alignment marks including the SiGe film 15A and the Ge film 15B are formed. The film thickness of the SiGe film 15A is not particularly limited, and may be, for example, 20 nm. The film thickness of the Ge film 15B is not particularly limited, and may be, for example, 80 nm.

Table 1 shows example optical properties of a Ge film having a film thickness of 80 nm.

TABLE 1

| | Ge | | |
|---|---|---|---|
| Wavelength | Reflectance | Transmittance | Absorptance |
| (nm) | (%) | (%) | (%) |
| 1,000 | 40.0 | 0 | 59.0 |
| 2,000 | 37.0 | 62.0 | 0 |
| 9,300 | 36.6 | 63.0 | 0 |

As shown in Table 1, when the Ge film's film thickness is 80 nm, its absorptance for infrared rays having a wavelength of 1,000 nm is 59.0%, so that the infrared rays used for photographing the alignment marks can be absorbed. Also, when the Ge film's film thickness is 80 nm, its transmittance for laser beams having a wavelength of 9,300 nm is 63.0%, so that the laser beams used for forming the modified layer portions can pass through the Ge film.

Next, a method of forming an SiGe film, which serves as alignment marks, will be described. The method of forming an SiGe film is the same as the Ge-film forming method described above with reference to FIGS. 15A to 15F, except that, according to the former method, after the SiGe film 15A having a film thickness of 100 nm is epitaxially grown in the sixth step, the Ge film 15B is not epitaxially grown. That is, alignment marks including the SiGe film 15A alone are formed. The process can therefore be shortened compared to when the alignment marks include the SiGe film 15A and the Ge film 15B. Note that the film thickness of the SiGe film 15A is by no means limited to 100 nm.

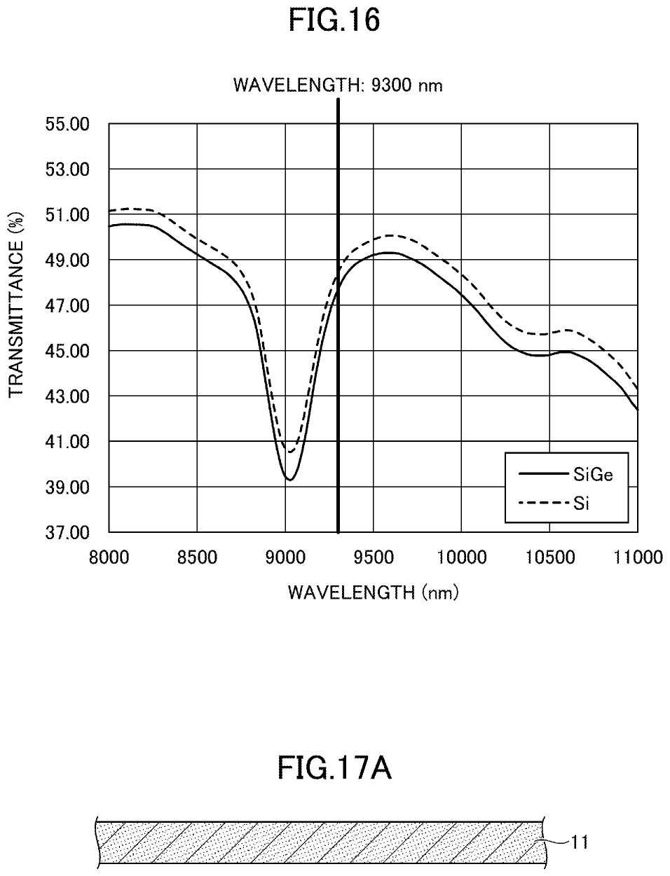

FIG. 16 shows example optical properties of the SiGe film having a film thickness of 100 nm. In FIG. 16, the solid line indicates the optical properties of the SiGe film, and the dashed line indicates the optical properties of bare silicon. The SiGe film that is 100 nm in film thickness has a transmittance of approximately 48% for laser beams having a wavelength of 9,300 nm, so that the laser beams used for forming the modified layer portions can pass through the SiGe film.

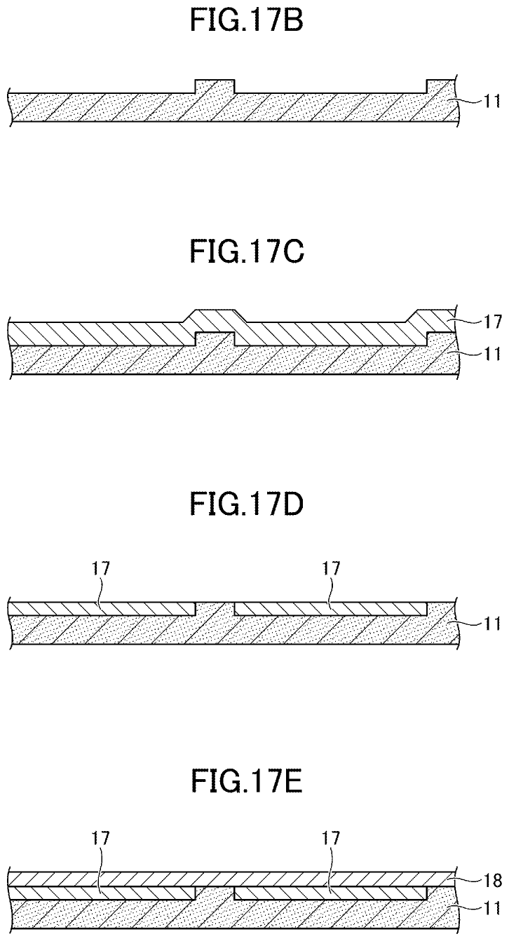

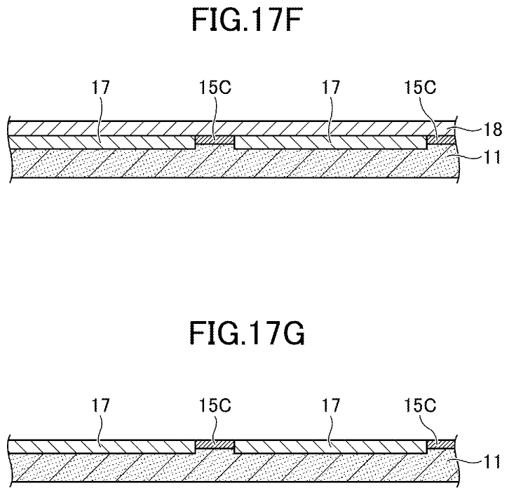

Next, a method of forming a metal silicide film, which serves as alignment marks, will be described with reference to FIGS. 17A to 17G. The forming method includes first to seventh steps. The first to fourth steps shown in FIGS. 17A to 17D are the same as the first to fourth steps shown in FIGS. 15A to 15D, and so their description will be omitted here.

In the fifth step, an Ni film 18 is formed over the surface of the silicon wafer 11, as shown in FIG. 17E. The Ni film 18 not only covers the exposed surface of the silicon wafer 11, but also covers the surface of the SiO₂ film 17 as well. The film thickness of the Ni film 18 is not particularly limited, and may be, for example, 20 nm.

In the sixth step, as shown in FIG. 17F, the silicon wafer 11 is heated so as to react the silicon wafer 11 and the Ni film 18, and form an NiSi₂ film 15C. The heating temperature of the silicon wafer 11 is not particularly limited, and may be 500 degrees Celsius, for example.

In the seventh step, as shown in FIG. 17G, the Ni film 18 is removed by SPM or the like, and the NiSi₂ film 15C is exposed. SPM is an aqueous solution containing sulfuric acid and hydrogen peroxide. The mixing ratio is, for example, 1:1:5 in mass ratio (H₂SO₄:H₂O:H₂O=1:1:5). The time for etching the Ni film 18 by SPM may be, for example, 15 minutes.

Alignment marks that include the NiSi₂ film 15C are formed. Note that the metal silicide is by no means limited to NiSi₂, and may be TiSi₂ or CoSi, for example. The film thickness of NiSi₂ is, for example, 20 nm to 40 nm. The film thickness of TiSi₂ is, for example, 50 nm to 80 nm. The film thickness of CoSi is, for example, 30 nm to 50 nm.

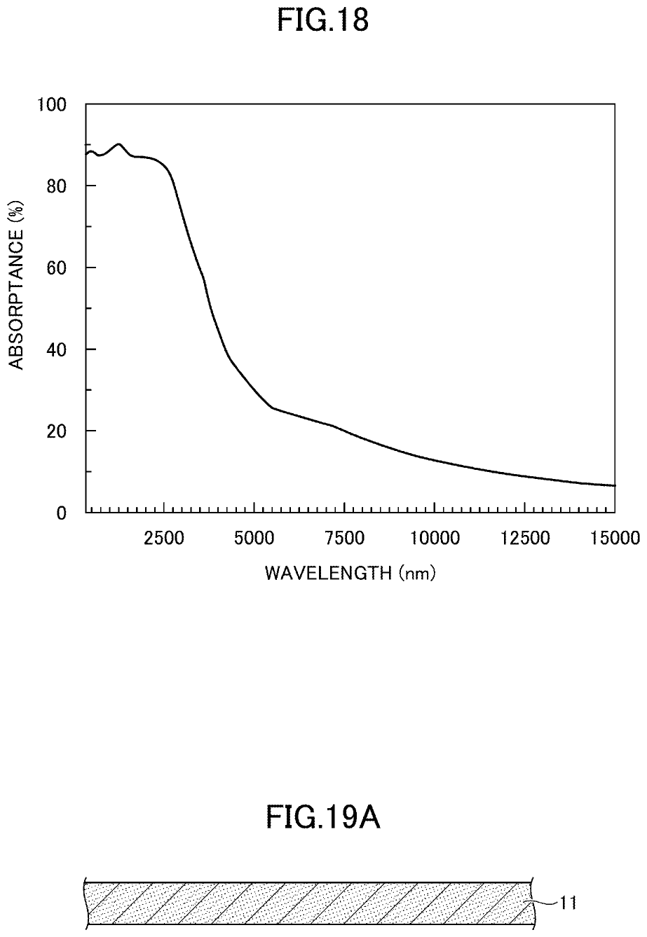

FIG. 18 shows an example of the absorptance of a TiSi₂ film having a film thickness of 210 nm. As shown in FIG. 18, when the TiSi₂ film's film thickness is 210 nm, its absorptance for infrared rays having a wavelength of 1,000 nm to 2,000 nm is approximately 90%, so that the infrared rays used for photographing the alignment marks can be absorbed. Also, when the TiSi₂ film's film thickness is 210 nm, its absorptance for laser beams having a wavelength of 9,300 nm is approximately 15%, so that the laser beams used for forming the modified layer portions can pass through the TiSi₂ film.

Note that, generally speaking, the thinner the film thickness, the lower the absorptance and the higher the transmittance. Therefore, when the TiSi₂ film's film thickness is 50 nm to 80 nm, its absorptance for laser beams having a wavelength of 9,300 nm is lower than approximately 15%, and therefore the laser beams used for forming the modified layer portions can pass through the TiSi₂ film.

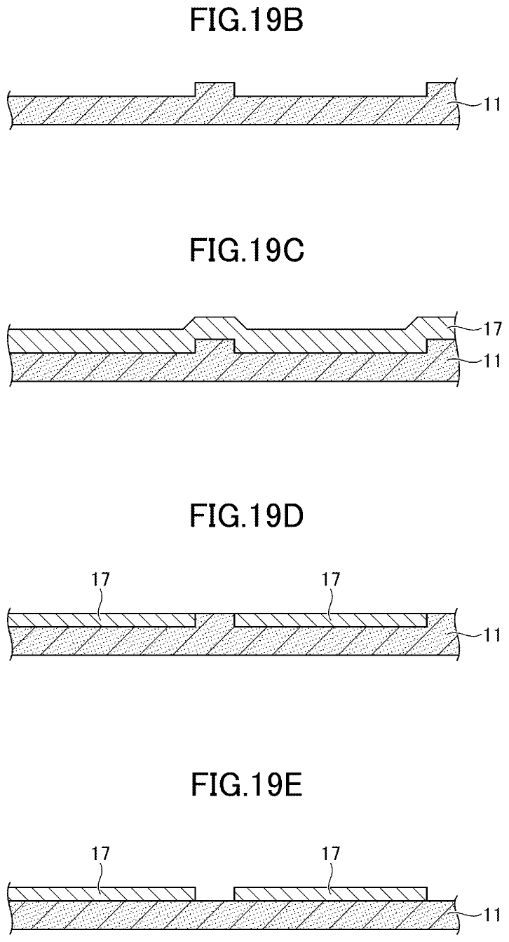

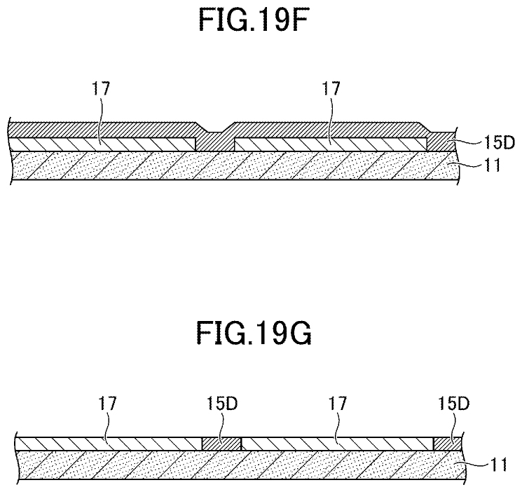

Next, a method of forming an AlN film, which serves as alignment marks, will be described with reference to FIGS. 19A to 19G. The forming method includes first to seventh steps. The first to fifth steps shown in FIGS. 19A to 19E are the same as the first to fifth steps shown in FIGS. 15A to 15E, and so their description will be omitted here.

In the sixth step, as shown in FIG. 19F, an AlN film 15D is formed over the surface of the silicon wafer 11, and the trenches are filled with the AlN film 15D. The AlN film 15D is formed, for example, by atomic layer deposition (ALD) using trimethylsilane (TMA).

To be more specific, plasmatized mixed gas (mixed gas containing Ar gas, H₂ gas, and N₂ gas), Ar gas, TMA gas, and Ar gas are repeatedly supplied, in this order, and an AlN film is formed. The mixing ratio of the mixed gas is, for example, 1:6:3 (Ar:H₂:N=1:6:3) by volume ratio. An NH group is formed on the surface of the silicon wafer 11 by supplying the plasmatized mixed gas. The NH group and the TMA gas react, and the AlN film is formed. Since the AlN film formed by this method exhibits a blue color, it is hereinafter also referred to as a “blue AlN film.” The blue AlN film contains impurities and exhibits a blue color. The film thickness of the blue AlN film is not particularly limited, and may be, for example, 100 nm.

In the seventh step, as shown in FIG. 19G, the AlN film 15D is flattened by CMP or the like, and part of the surface of the silicon wafer 11 is exposed. The rest of the surface of the silicon wafer 11 is covered with the AlN film 15D. The film thickness of the remaining AlN film 15D is not particularly limited, and may be, for example, 100 nm. Alignment marks that include the AlN film 15D are formed.

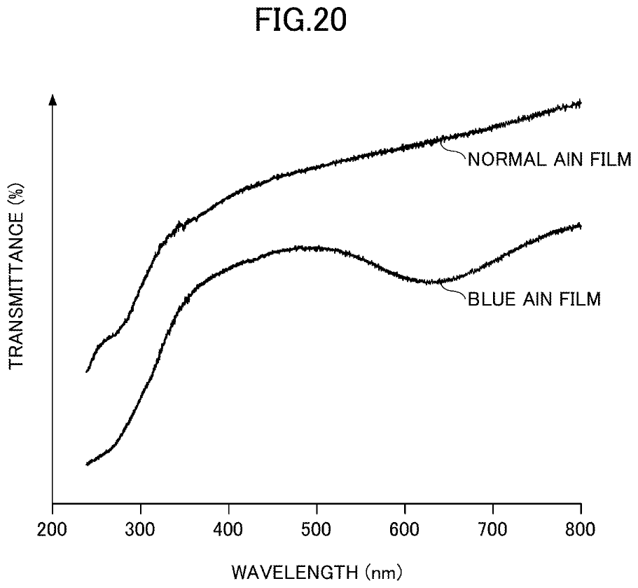

FIG. 20 shows an example of the transmittance of a blue AlN film having a film thickness of 100 nm. When the blue AlN film's film thickness is 100 nm, its transmittance for infrared rays having a wavelength of 1,000 nm is approximately 60%, so that the infrared rays used for photographing the alignment marks can be absorbed. The blue AlN film has a lower transmittance for infrared rays having a wavelength of 1,000 nm than a more typical AlN film, and therefore is suitable for alignment marks.

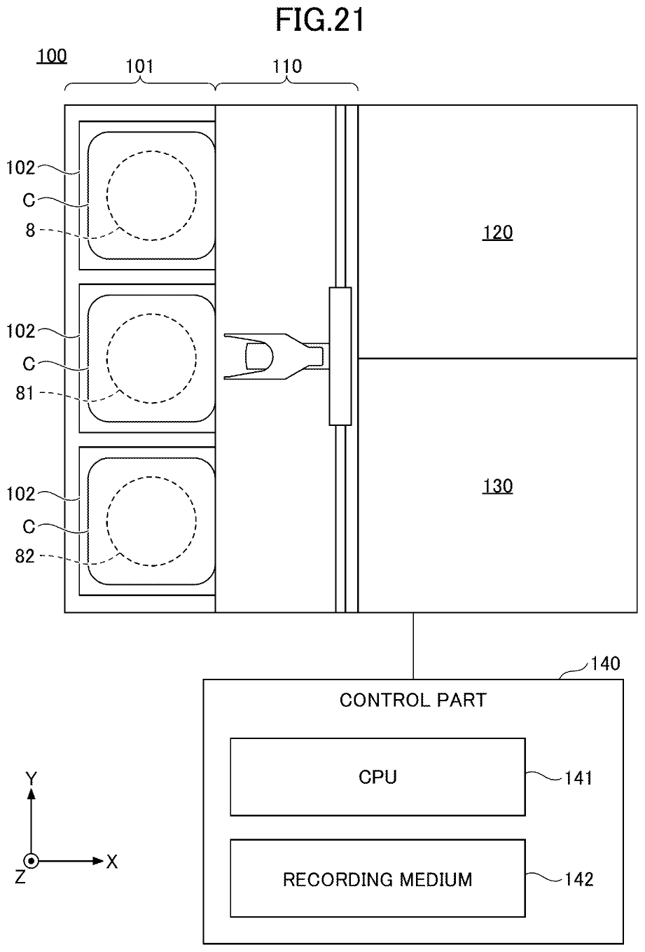

Next, a substrate processing device 100 that implements S61 and S62 of FIG. 3 will be described with reference to FIG. 21 and others. In FIG. 21, the X-axis direction, the Y-axis direction, and the Z-axis direction are perpendicular to each other. The X-axis direction and the Y-axis direction are the horizontal directions, and the Z-axis direction is the vertical direction. The substrate processing device 100 has a loading/unloading part 101, a transportation part 110, a laser processing part 120, a division part 130, and a control part 140.

The loading/unloading part 101 has a mounting part 102 where a cassette C is placed. The cassette C accommodates a plurality of stacked substrates 8, shown in FIG. 10 and others, at intervals, in the vertical direction. A stacked substrate 8 includes a plurality of chips 2A and 2B, a first substrate 1, and a second substrate 5. The stacked substrate 8 is divided into a first divided body 81 and a second divided body 82, at a dividing surface D, as shown in FIG. 12. Subsequently, the first divided body 81 and the second divided body 82 are separately accommodated in the cassette C. The first divided body 81 includes a silicon wafer 11, and, after being carried out of the substrate processing device 100, can be reused as a new first substrate 1. In order to reuse the silicon wafer 11 as a first substrate 1, an absorption layer 12 or the like may be re-formed over the surface of the silicon wafer 11. Conversely, the second divided body 82 includes the chips 2A and 2B, and, after being carried out of the substrate processing device 100, is subjected to S63 of FIG. 3, S7 of FIG. 1, and so forth. Note that the number of mounting parts 102 and the number of cassettes C are not limited to those shown in FIG. 21.

The transportation part 110 is placed next to the loading/unloading part 101, the laser processing part 120, and the division part 130, and transports the stacked substrates 8 and the like to these. The transportation part 110 has a holding mechanism for holding the stacked substrate 8 and the like. The holding mechanism is capable of moving horizontally (both in the X-axis direction and the Y-axis direction) and rotating about the vertical axis.

As shown in FIG. 11, the laser processing part 120 forms a plurality of modified layer portions M by using a laser beam LB2, on the dividing surface D where the first substrate 1 is going to be divided in the thickness direction. The modified layer portions M are formed in a dot-like shape and formed, for example, at the focal point or above the focal point. The laser processing part 120 includes, for example, a stage 121 that holds the first substrate 1, and an optical system 122 that irradiates the first substrate 1 held on the stage 121 with the laser beam LB2. The stage 121 is, for example, an XYθ stage or an XYZθ stage. The optical system 122 includes, for example, a condenser lens. The condenser lens converges the laser beam LB2 toward the first substrate 1. The optical system 122 may also include a galvanometer scanner.

The division part 130 divides the first substrate 1 from the modified layer portions M as starting points, as shown in FIG. 12. The division part 130 includes, for example, an upper chuck 131 and a lower chuck 132. The upper chuck 131 holds the first substrate 1, and the lower chuck 132 holds the second substrate 5. However, the positions of the first substrate 1 and the second substrate 5 may be reversed vertically. Next, when the upper chuck 131 rises with respect to the lower chuck 132, a crack CR expands planarly from the modified layer portions M as starting points, and the first substrate 1 is divided at the dividing surface D. In other words, the stacked substrate 8 is divided, at the dividing surface D, into the first divided body 81 and the second divided body 82. As the upper chuck 131 rises, the upper chuck 131 may rotate about the vertical axis. The first substrate 1 can be threaded off at the dividing surface D.

The control part 140 is, for example, a computer, and includes a central processing unit (CPU) 141 and a recording medium 142 such as a memory, as shown in FIG. 21. The recording medium 142 stores programs for controlling various processes executed in the substrate processing device 100. The control part 140 controls the operation of the substrate processing device 100 by causing the CPU 141 to execute the programs stored in the recording medium 142.

Although embodiments of the method of manufacturing a substrate with chips and the substrate processing device according to the present disclosure have been described above, the present disclosure is by no means limited to these embodiments. Various changes, modifications, substitutions, additions, deletions, and combinations are possible within the scope of the accompanying claims. These also naturally belong to the technical scope of the present disclosure.

This application is based on and claims priority to Japanese Patent Application No. 2021-013785, filed with Japan Patent Office on Jan. 29, 2021, and the entire contents of Japanese Patent Application No. 2021-013785 are incorporated herein by reference.

### DESCRIPTION OF THE REFERENCE NUMERALS

1 first substrate
2A, 2B chip
5 second substrate
6 third substrate
7 substrate with chips
8 stacked substrate
15 alignment mark
100 substrate processing device
110 transportation part
120 laser processing part
130 division part
LB2 laser beam
D dividing surface
M modified layer portion

1. A method of manufacturing a substrate with chips, the method comprising:
preparing a stacked substrate, the stacked substrate including:
a plurality of chips;
a first substrate to which the plurality of chips are temporarily bonded; and
a second substrate bonded to the first substrate via the plurality of chips; and
separating the plurality of chips bonded to the first substrate and the second substrate, from the first substrate, in order to bond the plurality of chips to one surface of a third substrate including a device layer,
wherein the first substrate, from which the plurality of chips are separated, includes alignment marks that are used to ensure alignment when the first substrate and the plurality of chips are bonded together, or that are used to measure misalignment after the first substrate and the plurality of chips are bonded together.

2. The method according to claim 1, wherein the separating of the plurality of chips from the first substrate includes:
forming a plurality of modified layer portions by using a laser beam, in a dividing surface where the first substrate is going to be divided in a thickness direction; and
dividing the first substrate by using the plurality of modified layer portions as starting points.

3. The method according to claim 2,
wherein the first substrate includes a silicon wafer and an absorption layer that is configured to absorb the laser beam between the silicon wafer and the plurality of chips, and
wherein the laser beam passes through the silicon wafer, and forms the modified layer portions in the absorption layer.

4. The method according to claim 3, wherein the alignment marks are formed between the silicon wafer and the absorption layer.

5. The method according to claim 4, wherein the laser beam passes through the silicon wafer and the alignment marks, and forms the modified layer portions in the absorption layer.

6. The method according to claim 2, wherein the alignment marks allow the laser beam to pass therethrough, and absorb an infrared ray having a different wavelength from that of the laser beam.

7. The method according to claim 6, wherein the alignment marks include a Ge film, an SiGe film, a metal silicide film, or a blue AlN film.

8. The method according to claim 6, wherein a wavelength of the laser beam is 8,800 nm to 11,000 nm.

9. The method according to claim 6, wherein the wavelength of the infrared ray is 1,000 nm to 2,000 nm.

10. The method according to claim 1, further comprising bonding, to the first substrate from which the plurality of chips are separated, chips that are different from the plurality of chips.

11. A substrate processing device comprising:
a transporter configured to transport a stacked substrate, the stacked substrate including:
a plurality of chips;
a first substrate to which the plurality of chips are temporarily bonded; and
a second substrate bonded to the first substrate via the plurality of chips;
a laser processor configured to form a plurality of modified layer portions by using a laser beam, in a dividing surface where the first substrate is going to be divided in a thickness direction; and
a divider configured to divide the first substrate by using the plurality of modified layer portions as starting points,
wherein the first substrate includes alignment marks that are used to ensure alignment when the first substrate and the plurality of chips are bonded together, or that are used to measure misalignment after the first substrate and the plurality of chips are bonded together, and
wherein the laser processor forms the plurality of modified layer portions, in the dividing surface, between the alignment marks and the plurality of chips.

12. The substrate processing device according to claim 11,
wherein the first substrate includes a silicon wafer and an absorption layer that is configured to absorb the laser beam between the silicon wafer and the plurality of chips, and
wherein the laser beam passes through the silicon wafer, and forms the modified layer portions in the absorption layer.

13. The substrate processing device according to claim 12,
wherein the alignment marks are formed between the silicon wafer and the absorption layer, and
wherein the laser beam passes through the silicon wafer and the alignment marks, and forms the modified layer portions in the absorption layer.
